(19) United States
(12) Patent Application Publication
(10) Pub. No.: US 2026/0372041 A1
(43) Pub. Date: Nov. 19, 2026

(54) MANUFACTURING METHOD OF SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/332,053

(22) Filed: Sep. 18, 2025

(30) Foreign Application Priority Data
May 13, 2025 (KR) 10-2025-0061672

(51) Int. Cl. H10W 20/00; H10W 46/00

(52) U.S. Cl. CPC H10W 20/067; H10W 20/057; H10W 20/081; H10W 46/00; H10W 46/301; H10W 46/503

(57) ABSTRACT

A method of manufacturing a semiconductor device includes: forming a redistribution insulating layer on a substrate; forming key trenches in the redistribution insulating layer, the key trenches being spaced apart from each other in a first direction on a top surface of the substrate; forming a redistribution conductive layer on a first side surface and a second side surface of each of the key trenches, the first side surface and the second side surface facing each other in the first direction and forming a contact point at which a first portion of the redistribution conductive layer formed on the first side surface and a second portion of the redistribution conductive layer formed on the second side surface contact each other; aligning an etching mask to a contact region including the contact point; and etching the redistribution conductive layer using the etching mask.

### CROSS-REFERENCE TO RELATED APPLICATIONS

The present application claims priority under 35 U.S.C. §119(a) to Korean Patent Application No. 10-2025-0061672 filed on May 13, 2025, which is incorporated herein by reference in its entirety.

### BACKGROUND

### 1. Technical Field

Embodiments of the present disclosure relate to a method of manufacturing a semiconductor device.

### 2. Related Art

As semiconductor devices become increasingly integrated, they may be separated through a cutting process such as sawing or dicing after being fabricated on a single wafer.

Meanwhile, as the integration of semiconductor devices progresses, the cutting process for semiconductor devices is facing technical challenges. For example, various keys may be disposed at locations where a cutting line passes, which may result in cracks or delamination around the regions where the keys are placed during the cutting process.

### SUMMARY

The objects of the embodiments of the present disclosure are not limited to those described herein, and other objects not explicitly stated will be clearly understood by those skilled in the art from the following description.

Embodiments of the present disclosure may provide a method of manufacturing a semiconductor device capable of minimizing defects generated during a cutting process.

Embodiments of the present disclosure may provide a method of manufacturing a semiconductor device, the method including: forming a redistribution insulating layer on a substrate including a chip region and a scribe lane region; forming trenches in the redistribution insulating layer of the scribe lane region, the trenches being spaced apart from each other in a first direction on a top surface of the substrate; forming a redistribution conductive layer on a first side surface and a second side surface of each of the trenches, the first side surface and the second side surface facing each other in the first direction and forming a contact point at which a first portion of the redistribution conductive layer formed on the first side surface and a second portion of the redistribution conductive layer formed on the second side surface contact each other; aligning an etching mask to a contact region including the contact point; and etching the redistribution conductive layer using the etching mask.

Embodiments of the present disclosure may provide a method of manufacturing a semiconductor device, the method including: forming a redistribution insulating layer on a substrate including a chip region and a scribe lane region; forming key trenches in the redistribution insulating layer of the scribe lane region, the key trenches being spaced apart from each other in a first direction on a top surface of the substrate and having a width of a top in the first direction equal to or less than a predetermined value; forming a redistribution conductive layer in the key trenches and on the redistribution insulating layer; aligning an etching mask to the redistribution conductive layer formed in the key trenches; and etching the redistribution conductive layer using the etching mask, wherein the predetermined value is twice a thickness of the redistribution conductive layer formed on a top surface of the redistribution insulating layer.

According to embodiments of the present disclosure, it is possible to provide a method of manufacturing a semiconductor device that may minimize defects occurring during a cutting process.

The advantages of the embodiments of the present disclosure are not limited to those described above, and other advantages not explicitly mentioned will be clearly understood by those skilled in the art from the descriptions of the claims.

### BRIEF DESCRIPTION OF THE DRAWINGS

The present disclosure will be more fully understood from the following detailed description and the accompanying drawings, which are provided for illustrative purposes only and are not intended to limit the scope of the disclosure.

FIG. 1 is a plan view illustrating an example of a structure of a semiconductor device according to embodiments of the present disclosure.

FIGS. 2-6 are cross-sectional views illustrating portions I–I′ and II–II′ of FIG. 1 in accordance with steps of a method of manufacturing a semiconductor device.

FIGS. 7-9 are cross-sectional views illustrating other examples of portions I–I′ and II–II′ of FIG. 1 in accordance with steps of a method of manufacturing a semiconductor device.

FIG. 10 is a cross-sectional view illustrating another example of portions I–I′ and II–II′ of FIG. 1 in accordance with steps of a method of manufacturing a semiconductor device.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc., a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc., each other via a fourth element. Here, the second element may be included in at least one of two or more elements that "are connected or coupled to", “contact or overlap”, etc., each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the accompanying drawings, two directions on the top surface of substrate 300 are defined as a first direction FD and a second direction SD, respectively, and a direction protruding perpendicularly from the top surface of substrate 300 is defined as a third direction VD. The first direction FD and the second direction SD may be substantially perpendicular to each other. The third direction VD is a direction perpendicular to both the first direction FD and the second direction SD. In the following specification, the term "perpendicular" or "perpendicular direction" will be used to mean substantially the same as the third direction VD. A direction indicated by an arrow in the drawings and its opposite direction represent the same direction.

Hereinafter, various embodiments of the present disclosure will be described in detail with reference to the accompanying drawings.

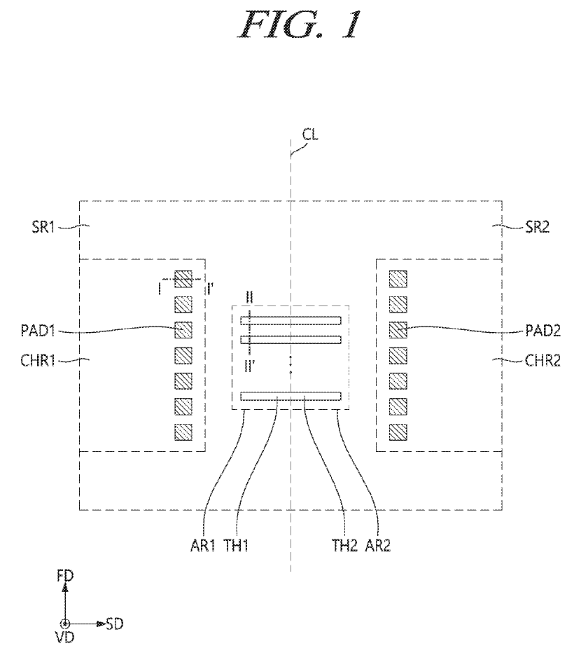

FIG. 1 is a plan view illustrating an example of a structure of a semiconductor device according to embodiments of the present disclosure. FIG. 1 illustrates the state of semiconductor devices before they are separated into individual chips after being formed on a single wafer.

Referring to FIG. 1, a first chip region CHR1 and a second chip region CHR2 are spaced apart from each other. The first chip region CHR1 and the second chip region CHR2 may respectively denote regions in which elements and wirings that constitute a single semiconductor device are disposed. For example, the elements and wirings disposed in the first chip region CHR1 may belong to a different semiconductor device from those disposed in the second chip region CHR2.

In one embodiment, the semiconductor device may include a Dynamic Random Access Memory (DRAM), Static Random Access Memory (SRAM), flash memory, Magnetoresistive RAM (MRAM), Phase-change RAM (PRAM), Ferroelectric RAM (FRAM), Resistive RAM (RRAM), or a combination thereof, but is not limited thereto.

A first scribe lane region SR1 may be disposed around the first chip region CHR1. The first scribe lane region SR1 may surround the first chip region CHR1. A second scribe lane region SR2 may be disposed around the second chip region CHR2. The second scribe lane region SR2 may surround the second chip region CHR2. The second scribe lane region SR2 may be continuous with the first scribe lane region SR1. The first scribe lane region SR1 and the second scribe lane region SR2 may be defined by a cutting line CL. In one embodiment, the first and second scribe lane regions SR1 and SR2 may be separated from each other by a cutting process. The first scribe lane region SR1 and the second scribe lane region SR2 may belong to different semiconductor devices.

In one embodiment, the first chip region CHR1 and the first scribe lane region SR1 may be included in a single semiconductor device (e.g., a first semiconductor device). The second chip region CHR2 and the second scribe lane region SR2 may be included in another semiconductor device (e.g., a second semiconductor device) that is different from the first semiconductor device.

Hereinafter, for convenience of description, the semiconductor device according to embodiments of the present disclosure will be referred to as the first semiconductor device.

A first key region AR1 may be located in the first scribe lane region SR1. A second key region AR2 may be located in the second scribe lane region SR2. The first key region AR1 and the second key region AR2 may denote regions in which various keys necessary for alignment of the semiconductor device are disposed. In one embodiment, the first key region AR1 and the second key region AR2 may include various keys such as alignment keys, overlay keys, or a combination thereof.

According to an embodiment of the present disclosure, a first key trench TH1 may be disposed in the first key region AR1, and a second key trench TH2 may be disposed in the second key region AR2. The first key trench TH1 may be continuous with the second key trench TH2. The first key trench TH1 and the second key trench TH2 may be spaced apart from each other in a first direction FD. The first key trench TH1 and the second key trench TH2 may extend in a direction perpendicular to a direction in which a cutting line CL extends.

A first chip pad PAD1 may be located in the first chip region CHR1. A second chip pad PAD2 may be located in the second chip region CHR2. In one embodiment, the first chip pad PAD1 and the second chip pad PAD2 may be pads for supplying signals to circuits and wirings located in the chip regions.

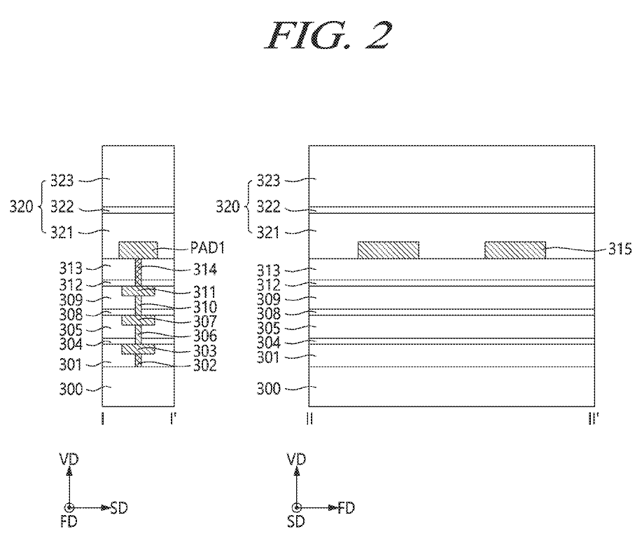

FIGS. 2-6 are cross-sectional views illustrating examples of portions I–I′ and II–II′ of FIG. 1 in accordance with steps of a method of manufacturing a semiconductor device.

Referring to FIG. 2, a first insulating layer 301, a first contact 302, a first wiring 303, a first interlayer insulating layer 304, a second insulating layer 305, a second contact 306, a second wiring 307, a second interlayer insulating layer 308, a third insulating layer 309, a third contact 310, a third wiring 311, a third interlayer insulating layer 312, a fourth insulating layer 313, and a fourth contact 314 may be sequentially formed on a substrate 300.

The substrate 300 may include a semiconductor substrate such as a silicon wafer or a silicon-on-insulator (SOI) wafer. The substrate 300 may include a group III–V compound semiconductor substrate, for example, gallium arsenide (GaAs). The substrate 300 may include single-crystal silicon, polysilicon, amorphous silicon, single-crystal silicon-germanium, polycrystalline silicon-germanium, carbon-doped silicon, or a combination thereof.

The first insulating layer 301, the first interlayer insulating layer 304, the second insulating layer 305, the second interlayer insulating layer 308, the third insulating layer 309, the third interlayer insulating layer 312, and the fourth insulating layer 313 may include silicon oxide, silicon nitride, silicon oxynitride, high-k dielectric material, low-k dielectric material, or a combination thereof.

The first contact 302, the first wiring 303, the second contact 306, the second wiring 307, the third contact 310, the third wiring 311, and the fourth contact 314 may include a conductive material such as a metal, metal oxide, metal nitride, metal silicide, polysilicon, conductive carbon, or a combination thereof.

The first chip pad PAD1 and a conductive layer 315 may be formed on the fourth contact 314 and the fourth insulating layer 313. The first chip pad PAD1 may be connected to the fourth contact 314. The conductive layer 315 may be disposed spaced apart in the first direction FD. The conductive layer 315 may contact a bottom surface of a redistribution insulating layer 320. The first chip pad PAD1 and the conductive layer 315 may include a conductive material such as a metal, metal oxide, metal nitride, metal silicide, polysilicon, conductive carbon, or a combination thereof. In one embodiment, the first chip pad PAD1 and the conductive layer 315 may include aluminum (Al).

The redistribution insulating layer 320 may be formed on the first chip pad PAD1, the conductive layer 315, and the fourth insulating layer 313. The redistribution insulating layer 320 may include silicon oxide, silicon nitride, silicon oxynitride, high-k dielectric material, low-k dielectric material, or a combination thereof. The redistribution insulating layer 320 may include a first redistribution insulating layer 321, a second redistribution insulating layer 322, and a third redistribution insulating layer 323.

The first redistribution insulating layer 321 may be formed to cover a side surface and a top surface of the first chip pad PAD1 and the conductive layer 315. In one embodiment, the first redistribution insulating layer 321 may include an oxide such as a high-density plasma (HDP) oxide. In one embodiment, the first redistribution insulating layer 321 may have a planar top surface.

The second redistribution insulating layer 322 may be formed on the first redistribution insulating layer 321. In one embodiment, the second redistribution insulating layer 322 may include silicon nitride.

A third redistribution insulating layer 323 may be formed on the second redistribution insulating layer 322. In one embodiment, the third redistribution insulating layer 323 may include silicon oxide. In one embodiment, a thickness of the third redistribution insulating layer 323 may be greater than a thickness of the first redistribution insulating layer 321 and a thickness of the second redistribution insulating layer 322.

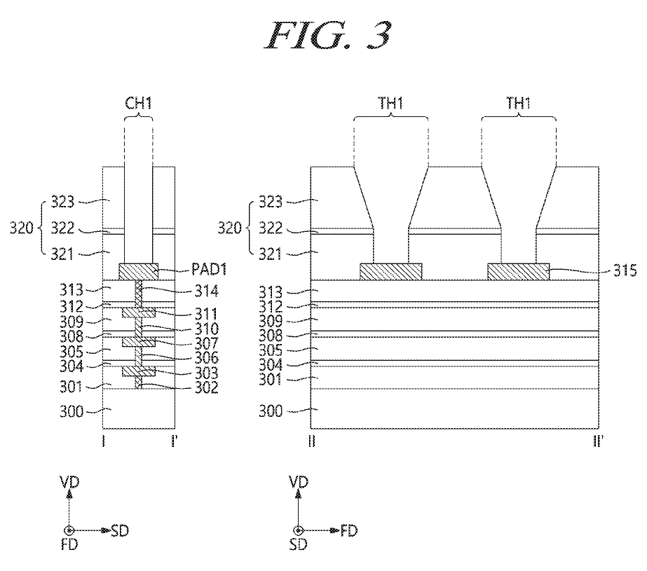

Referring to FIG. 3, a first chip hole CH1 and a first key trench TH1 may be formed in the redistribution insulating layer 320. In one embodiment, a process for forming the first chip hole CH1 may be performed in the same process step as a process for forming the first key trench TH1. The process of forming the first chip hole CH1 and the first key trench TH1 may include etching the first redistribution insulating layer 321, the second redistribution insulating layer 322, and the third redistribution insulating layer 323.

By the etching process of the first, second, and third redistribution insulating layers 321, 322, and 323, a top surface of the first chip pad PAD1 and a top surface of the conductive layer 315 may be exposed.

The first chip hole CH1 and the first key trench TH1 may respectively overlap the first chip pad PAD1 and the conductive layer 315.

In one embodiment, when the third redistribution insulating layer 323 is etched, an upper portion of the third redistribution insulating layer 323 may be etched more than a lower portion.

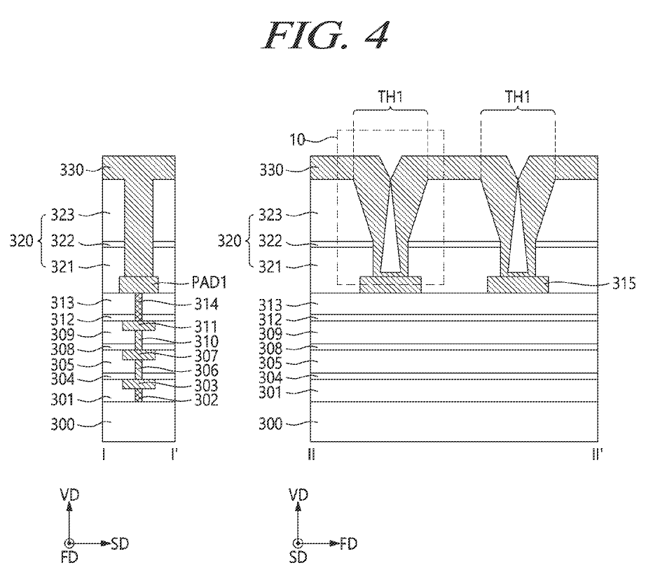

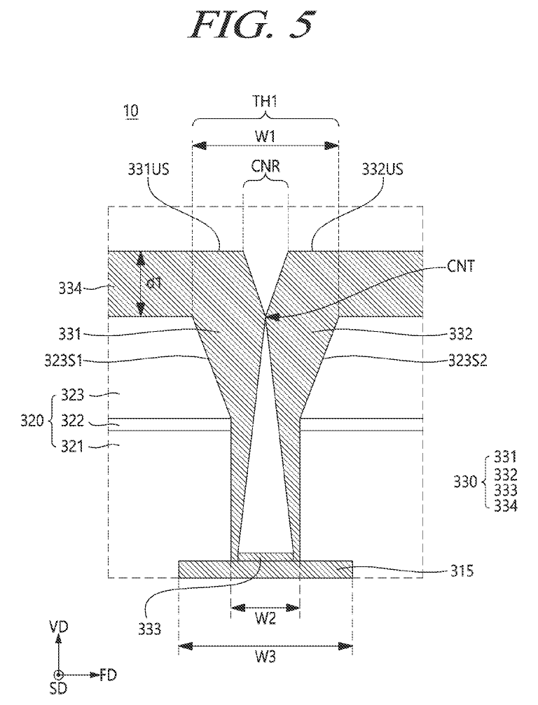

Referring to FIGS. 4-5, a redistribution conductive layer 330 may be formed in the first chip hole CH1 and the first key trench TH1. The redistribution conductive layer 330 may be formed inside the first chip hole CH1 and the first key trench TH1, and on a top surface of the third redistribution insulating layer 323. The redistribution conductive layer 330 may include a conductive material such as a metal, metal oxide, metal nitride, metal silicide, polysilicon, conductive carbon, or a combination thereof. In one embodiment, the redistribution conductive layer 330 may include aluminum.

In one embodiment, the redistribution conductive layer 330 may completely fill the inside of the first chip hole CH1. The redistribution conductive layer 330 formed in the first chip hole CH1 may contact the first chip pad PAD1. In one embodiment, the redistribution conductive layer 330 may fill at least a portion of the inside of the first key trench TH1. The redistribution conductive layer 330 formed in the first key trench TH1 may contact the conductive layer 315.

The redistribution conductive layer 330 may include a first portion 331, a second portion 332, a third portion 333, and a fourth portion 334.

The first portion 331 and the second portion 332 of the redistribution conductive layer 330 may refer to portions disposed on side surfaces 323S1 and 323S2 of the third redistribution insulating layer 323 exposed by the first key trench TH1. The side surfaces 323S1 and 323S2 of the third redistribution insulating layer 323 exposed by the first key trench TH1 may include a first side surface 323S1 and a second side surface 323S2 that face each other in the first direction FD. The first portion 331 of the redistribution conductive layer 330 may be located on the first side surface 323S1 of the third redistribution insulating layer 323, and the second portion 332 may be located on the second side surface 323S2 of the third redistribution insulating layer 323.

The third portion 333 of the redistribution conductive layer 330 may be located at a bottom of the first key trench TH1 and may be continuous with the first portion 331 and the second portion 332 of the redistribution conductive layer 330. The third portion 333 of the redistribution conductive layer 330 may be connected to the conductive layer 315.

The fourth portion 334 of the redistribution conductive layer 330 may refer to a portion located on a top surface of the redistribution insulating layer 320. The fourth portion 334 of the redistribution conductive layer 330 may be continuous with the first portion 331 and the second portion 332.

In one embodiment, the first portion 331 and the second portion 332 of the redistribution conductive layer 330 may be in contact with each other. The contact point CNT at which the first portion 331 and the second portion 332 of the redistribution conductive layer 330 are in contact with each other may be formed between the first side surface 323S1 and the second side surface 323S2 of the third redistribution insulating layer 323. The contact point CNT at which the first portion 331 and the second portion 332 of the redistribution conductive layer 330 may be included in a contact region CNR.

In the present specification, the contact region CNR may refer to the region between uppermost surfaces of the redistribution conductive layer 330. For example, the contact region CNR may refer to a region between a top surface 331US of the first portion 331 and a top surface 332US of the second portion 332. The contact region CNR may include the contact point CNT at which the first portion 331 and the second portion 332 of the redistribution conductive layer 330 are in contact with each other.

The contact point CNT at which the first portion 331 and the second portion 332 are in contact with each other may be spaced apart in a vertical direction from a bottom of the first key trench TH1. In FIG. 5, the contact point CNT is illustrated as a single point; however, an area of the contact point CNT at which the first portion 331 and the second portion 332 are in contact with each other is not limited thereto.

In one embodiment, a width of the first portion 331 and the second portion 332 in the first direction FD may decrease toward the bottom of the first key trench TH1. The bottom of the first key trench TH1 may refer to a surface substantially the same as a top surface of the conductive layer 315. The width in the first direction FD of the first portion 331 and the second portion 332 may be the smallest at the bottom of the first key trench TH1.

During the formation of the redistribution conductive layer 330, third portion 333 of the redistribution conductive layer 330 may not be exposed. The third portion 333 may be spaced apart in a vertical direction from the contact point CNT where the first portion 331 and the second portion 332 are in contact with each other.

In one embodiment, the contact point CNT at which the first portion 331 and the second portion 332 are in contact with each other may be located below the top surface of the fourth portion 334 in the vertical direction. For example, a distance from the top surface of the fourth portion 334 to the substrate 300 may be greater than a distance from the contact point CNT to the substrate 300.

In one embodiment, a vertical thickness d1 of the fourth portion 334 may be 1.5 µm. In one embodiment, a width W1 of a top of the first key trench TH1 in the first direction FD may be equal to or less than twice the vertical thickness d1 of the fourth portion 334.

In one embodiment, when the vertical thickness d1 of the fourth portion 334 of the redistribution conductive layer 330 is 1.5 µm, the width W1 of the top of the first key trench TH1 in the first direction FD may be between 1 µm and 3 µm.

When the width W1 of the top of the first key trench TH1 in the first direction FD is equal to or less than 1 µm, the redistribution conductive layer 330 formed at a bottom of the first chip hole CH1 may not have a sufficient width. In this case, an electrical connection between the redistribution conductive layer 330 and the first chip pad PAD1 may become problematic. Accordingly, the width W1 of the top of the first key trench TH1 in the first direction FD must be at least 1 µm.

When a width W1 of a top of the first key trench TH1 in the first direction FD is equal to or greater than twice a vertical thickness d1 of the fourth portion 334 of the redistribution conductive layer 330—for example, when the vertical thickness d1 of the fourth portion 334 is 1.5 µm and the width W1 of the top of the first key trench TH1 in the first direction FD is equal to or greater than 3 µm—the width of the first key trench TH1 in the first direction FD may become too large, resulting in an increased amount of the redistribution conductive layer 330 remaining in the first key trench TH1 during subsequent processes. This may cause defects during the cutting process. Accordingly, the width W1 of the top of the first key trench TH1 in the first direction FD should be equal to or less than 3 µm.

In one embodiment, a width W2 of a bottom of the first key trench TH1 in the first direction FD may be smaller than the width W1 of the top of the first key trench TH1 in the first direction FD. The width W2 of the bottom of the first key trench TH1 in the first direction FD may also be smaller than a width W3 of the conductive layer 315 in the first direction FD. In one embodiment, the width W2 of the bottom of the first key trench TH1 in the first direction FD may be equal to or less than 2 µm. If the width W2 of the bottom of the first key trench TH1 in the first direction FD exceeds 2 µm, as previously described, defects may occur during the cutting process. Accordingly, the width W2 should be equal to or less than 2 µm.

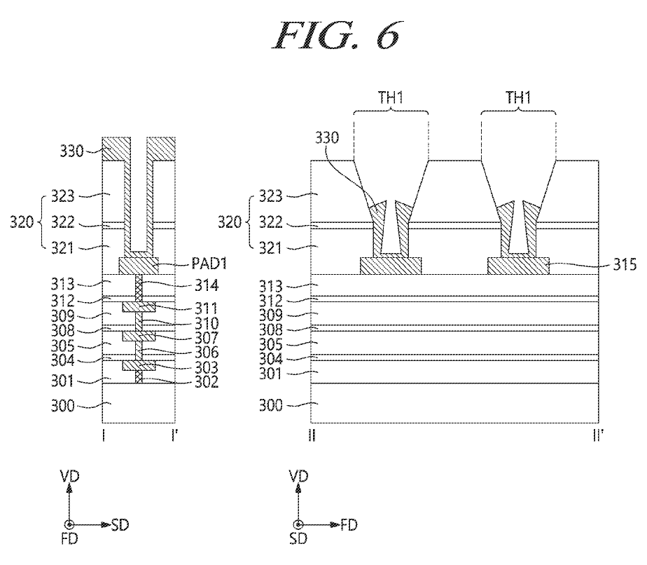

Referring to FIG. 6, at least a portion of the redistribution conductive layer 330 formed in the first chip hole CH1 and the first key trench TH1 may be removed.

In embodiments of the present disclosure, a process of etching the redistribution conductive layer 330 formed in the first chip hole CH1 may be performed by aligning an etching mask to the contact region CNR described with reference to FIG. 5. The etching mask may be aligned to the redistribution conductive layer 330 located in the first key trench TH1.

In one embodiment, the alignment position of the etching mask may be identified by light reflection or diffraction caused by a height difference between the contact point CNT, where the first portion 331 and the second portion 332 of the redistribution conductive layer 330 are in contact, and a top surface of the fourth portion 334.

In one embodiment, after at least a portion of the redistribution conductive layer 330 is removed, a top surface of the redistribution conductive layer 330 remaining in the first key trench TH1 may be located lower than a top surface of the redistribution insulating layer 320.

According to embodiments of the present disclosure, the width of the first key trench TH1 in the first direction FD may be formed to be small. Accordingly, the amount of the redistribution conductive layer 330 remaining in the first key trench TH1 at the etching step may be reduced. Thus, defects such as separation failures that may occur due to the residual redistribution conductive layer 330 in the first key trench TH1 during the cutting process can be minimized.

In addition, during the etching of the redistribution conductive layer 330, the etching mask may be aligned to the region where the first portion 331 and the second portion 332 are in contact. As previously described, the alignment position of the etching mask may be determined by light reflection or diffraction caused by the height difference between the contact point CNT, where the first portion 331 and the second portion 332 of the redistribution conductive layer 330 and the top surface of the fourth portion 334. Accordingly, even if the width of the first key trench TH1 in the first direction FD is reduced, the redistribution conductive layer 330 may be etched using the same etching mask as that used before the reduction.

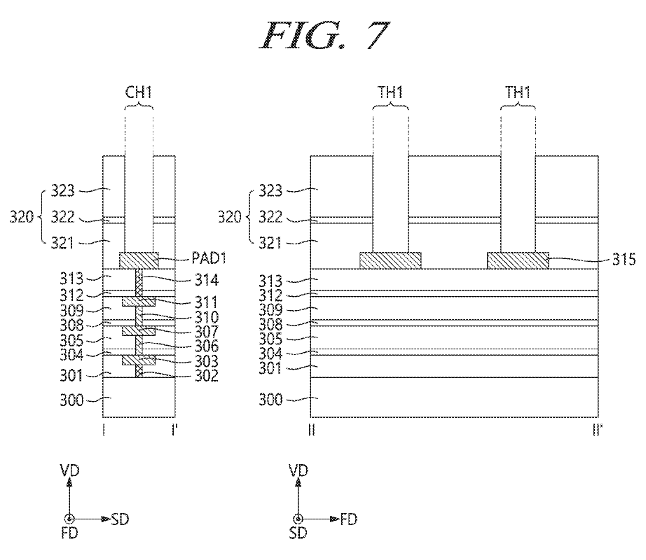

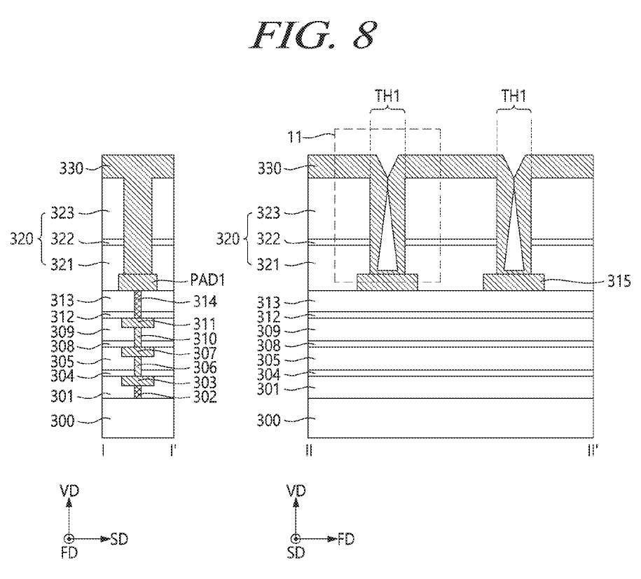

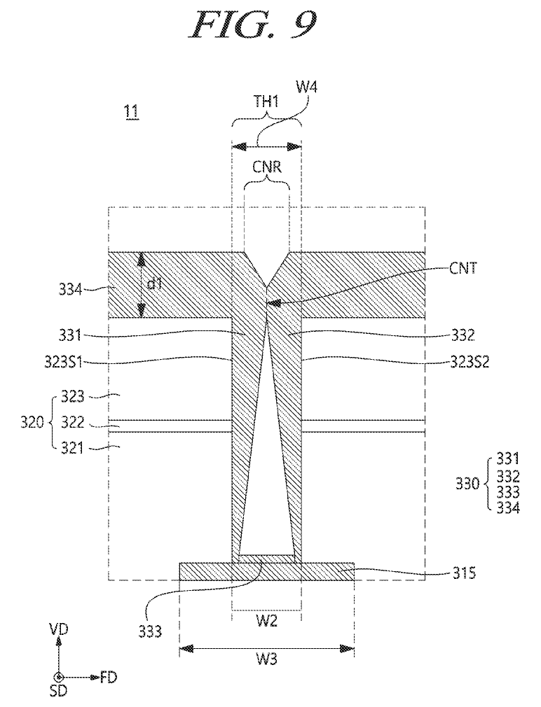

FIGS. 7-9 illustrate other cross-sectional views of the I–I’ and II–II’ portions in FIG. 1, according to the sequence of steps in the method of manufacturing a semiconductor device.

The semiconductor device shown in FIG. 7 may be formed by the same method as described with reference to FIG. 2.

Referring to FIG. 7, a first chip hole CH1 and a first key trench TH1 may be formed in the redistribution insulating layer 320. In one embodiment, the process of forming the first chip hole CH1 may be performed in the same step as the process of forming the first key trench TH1. The process of forming the first chip hole CH1 and the first key trench TH1 may include etching the first redistribution insulating layer 321, the second redistribution insulating layer 322, and the third redistribution insulating layer 323.

Through the etching process of the first, second, and third redistribution insulating layers 321, 322, and 323, top surfaces of the first chip pad PAD1 and the conductive layer 315 may be exposed.

The first chip hole CH1 and the first key trench TH1 may respectively overlap the first chip pad PAD1 and the conductive layer 315.

In one embodiment, a width of a bottom of the first key trench TH1 in the first direction FD may be substantially the same as a width of a top of the first key trench TH1 in the first direction FD.

Referring to FIGS. 7-9, the redistribution conductive layer 330 may be formed in the first chip hole CH1 and the first key trench TH1. The redistribution conductive layer 330 may be formed inside the first chip hole CH1 and the first key trench TH1, and on a top surface of the third redistribution insulating layer 323.

In one embodiment, the redistribution conductive layer 330 may completely fill the inside of the first chip hole. The redistribution conductive layer 330 formed inside the first chip hole CH1 may be in contact with the first chip pad PAD1. In one embodiment, the redistribution conductive layer 330 may fill at least a portion of the first key trench TH1. The redistribution conductive layer 330 formed in the first key trench TH1 may be in contact with the conductive layer 315.

The redistribution conductive layer 330 may include the first portion 331, the second portion 332, the third portion 333, and the fourth portion 334.

The first portion 331 of the redistribution conductive layer 330 may be located on a first side surface 323S1 of the third redistribution insulating layer 323. The second portion 332 of the redistribution conductive layer 330 may be located on a second side surface 323S2 of the third redistribution insulating layer 323. The third portion 333 of the redistribution conductive layer 330 may be connected to the conductive layer 315 and may be continuous with the first portion 331 and the second portion 332. The fourth portion 334 may also be continuous with the first portion 331 and the second portion 332.

In one embodiment, the first portion 331 and the second portion 332 of the redistribution conductive layer 330 may be in contact with each other. A contact point CNT between the first portion 331 and the second portion 332 may be formed between the first and second side surfaces 323S1 and 323S2 of the third redistribution insulating layer 323. The contact point CNT between the first portion 331 and the second portion 332 may be included in the contact region CNR. That is, the contact region CNR may include the contact point CNT where the first portion 331 and the second portion 332 come into contact. The contact point CNT may be spaced apart in a vertical direction from a bottom of the first key trench TH1. In one embodiment, the area of the contact point CNT where the first portion 331 and the second portion 332 come into contact may be larger than the area of the contact point CNT described with reference to FIG. 5.

In one embodiment, a width of the first portion 331 and the second portion 332 in the first direction FD may decrease toward the bottom of the first key trench TH1. The width of the first portion 331 and the second portion 332 in the first direction FD at the bottom may be the smallest.

During the formation of the redistribution conductive layer 330, the third portion 333 of the redistribution conductive layer 330 may not be exposed. The third portion 333 may be spaced apart in a vertical direction from the contact point CNT where the first portion 331 and the second portion 332 is in contact with each other.

In one embodiment, the contact point CNT where the first portion 331 and the second portion 332 are in contact with each other may be located below a top surface of the fourth portion 334 in a vertical direction. For example, a distance from the top surface of the fourth portion 334 to the substrate 300 may be greater than a distance from the contact point CNT to the substrate 300.

In one embodiment, a vertical thickness d1 of the fourth portion 334 may be 1.5 µm. A width W4 of a top of the first key trench TH1 in the first direction FD may be equal to or less than twice the vertical thickness d1.

When the vertical thickness d1 of the fourth portion 334 is 1.5 µm, the width W4 of the top of the first key trench TH1 in the first direction FD may be equal to or less than 3 µm. As described above, if the width W4 of the top of the first key trench TH1 in the first direction FD is equal to or greater than twice the thickness d1—for example, if the vertical thickness d1 of the fourth portion 334 is 1.5 μm and the width W4 of the top of the first key trench TH1 in the first direction FD is 3 μm or more—a defect may occur during the cutting process. Accordingly, the width W4 of the top of the first key trench TH1 in the first direction FD should be equal to or less than 3 µm.

In one embodiment, a width W2 of a bottom of the first key trench TH1 in the first direction FD may be substantially the same as the width W4 of the top in the first direction FD. The width W2 of the bottom of the first key trench TH1 in the first direction FD may be smaller than the width W3 of the conductive layer 315 in the first direction FD. Because the width W2 of the bottom of the first key trench TH1 in the first direction FD may be equal to the width W4 of the top of the first key trench TH1 in the first direction FD, the width W2 of the bottom of the first key trench TH1 in the first direction FD may also be 3 μm or less.

After the redistribution conductive layer 330 is formed, a process of etching the redistribution conductive layer 330 formed in the first chip hole CH1 may be performed similarly to the method described with reference to FIG. 6. For example, the process of etching the redistribution conductive layer 330 formed in the first chip hole CH1 may be performed by aligning an etching mask to the contact region CNR.

In one embodiment, when the widths W4 and W2 of the top and bottom of the first key trench TH1 are the same in the first direction FD, the amount of redistribution conductive layer 330 remaining in the first key trench TH1 after etching may be less than the amount remaining in the first key trench TH1 as described with reference to FIG. 6. Accordingly, during the cutting process, separation defects caused by the remaining redistribution conductive layer 330 in the first key trench TH1 can be more effectively prevented.

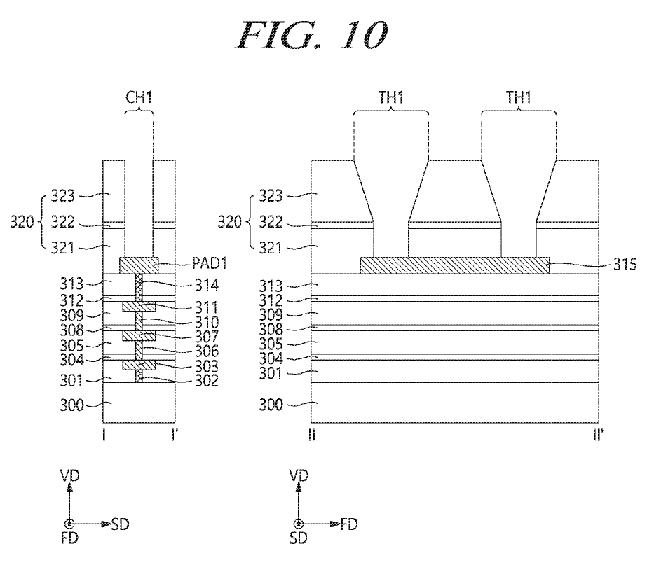

FIG. 10 illustrates another cross-sectional view of the I–I’ and II–II’ portions in FIG. 1, according to the sequence of the method for manufacturing the semiconductor device.

Referring to FIG. 10, a first insulating layer 301, a first contact 302, a first wiring 303, a first interlayer insulating layer 304, a second insulating layer 305, a second contact 306, a second wiring 307, a second interlayer insulating layer 308, a third insulating layer 309, a third contact 310, a third wiring 311, a third interlayer insulating layer 312, a fourth insulating layer 313, and a fourth contact 314 may be sequentially formed on the substrate 300.

The conductive layer 315 may be formed on the fourth insulating layer 313. The conductive layer 315 may contact a bottom surface of the redistribution insulating layer 320. The first key trench TH1 may be formed on the conductive layer 315. At least two first key trenches TH1 may overlap a single conductive layer 315. The conductive layer 315 shown in FIG. 10 may have a greater width in the first direction FD than the conductive layer 315 described with reference to FIG. 2.

In one embodiment, when the conductive layer 315 has a greater width, it may more effectively prevent the top surface of the fourth insulating layer 313 from being etched during the etching process for forming the first key trench TH1.

The processes following the formation of the first chip hole CH1 and the first key trench TH1 may proceed in the same manner as the method described with reference to FIGS. 4-6.

The foregoing description is merely illustrative of the technical concepts of the present disclosure. Those skilled in the art to which the present disclosure pertains will appreciate that various modifications and changes can be made without departing from the scope and technical concepts of the present disclosure. Furthermore, the embodiments described herein are provided for illustrative purposes and are not intended to limit the scope of the present disclosure. The protection scope of the present disclosure should be interpreted based on the claims, and all technical concepts falling within the scope of equivalence thereof should be construed as being included within the scope of the present disclosure.

What is claimed is:

1. A method of manufacturing a semiconductor device, the method comprising:
forming a redistribution insulating layer on a substrate including a chip region and a scribe lane region;
forming key trenches in the redistribution insulating layer of the scribe lane region, the key trenches being spaced apart from each other in a first direction on a top surface of the substrate;
forming a redistribution conductive layer on a first side surface and a second side surface of each of the key trenches, the first side surface and the second side surface facing each other in the first direction and forming a contact point at which a first portion of the redistribution conductive layer formed on the first side surface and a second portion of the redistribution conductive layer formed on the second side surface contact each other;
aligning an etching mask to a contact region including the contact point; and
etching the redistribution conductive layer using the etching mask.

2. The method of claim 1,
wherein the contact point is spaced apart in a vertical direction from a bottom of each of the key trenches.

3. The method of claim 2,
wherein the redistribution conductive layer further comprises a third portion formed at the bottom of each of the key trenches to be continuous with the first portion and the second portion, and
wherein a top surface of the third portion is not exposed after the forming of the redistribution conductive layer.

4. The method of claim 3,
wherein the third portion is spaced apart in the vertical direction from the contact point.

5. The method of claim 1,
wherein the redistribution conductive layer further comprises a fourth portion formed on a top surface of the redistribution insulating layer, and
wherein a width of a top of each of the key trenches in the first direction is equal to or less than twice a thickness of the fourth portion in a vertical direction.

6. The method of claim 5,
wherein the width of the top of each of the key trenches in the first direction is between 1 μm and 3 μm.

7. The method of claim 5,
wherein a distance from a top surface of the fourth portion to the substrate is greater than a distance from the contact point to the substrate.

8. The method of claim 1,
wherein a width of a bottom of each of the key trenches in the first direction is equal to or less than 2 μm.

9. The method of claim 1,
wherein a width of a top of each of the key trenches in the first direction is greater than a width of a bottom of each of the key trenches in the first direction.

10. The method of claim 1,
wherein a width of a top of each of the key trenches in the first direction is a same as a width of a bottom of each of the key trenches in the first direction.

11. The method of claim 1, further comprising forming a conductive layer contacting a bottom surface of the redistribution insulating layer and overlapping the key trenches.

12. The method of claim 11,
wherein a width of the conductive layer in the first direction is greater than a width of a bottom of each of the key trenches in the first direction.

13. A method of manufacturing a semiconductor device, the method comprising:
forming a redistribution insulating layer on a substrate including a chip region and a scribe lane region;
forming key trenches in the redistribution insulating layer of the scribe lane region, the key trenches being spaced apart from each other in a first direction on a top surface of the substrate and having a width of a top in the first direction equal to or less than a predetermined value;
forming a redistribution conductive layer in the key trenches and on the redistribution insulating layer;
aligning an etching mask to the redistribution conductive layer formed in the key trenches; and
etching the redistribution conductive layer using the etching mask,
wherein the predetermined value is twice a thickness of the redistribution conductive layer formed on a top surface of the redistribution insulating layer.

14. The method of claim 13,
wherein a first side surface and a second side surface of each of the key trenches face each other in the first direction, and
wherein a first portion of the redistribution conductive layer formed on the first side surface and a second portion of the redistribution conductive layer formed on the second side surface contact each other.

15. The method of claim 14,
wherein the etching mask is aligned to a contact region including a contact point at which the first portion and the second portion contact each other.

16. The method of claim 14,
wherein the redistribution conductive layer further comprises a third portion formed at a bottom of each of the key trenches to be continuous with the first portion and the second portion, and
wherein a top surface of the third portion is not exposed after the forming of the redistribution conductive layer.

17. The method of claim 15,
wherein a distance from a top surface of a portion of the redistribution conductive layer formed on the top surface of the redistribution insulating layer to the substrate is greater than a distance from the contact point.

18. The method of claim 13,
wherein a width of a top of each of the key trenches in the first direction is greater than a width of a bottom of each of the key trenches in the first direction.

19. The method of claim 13,
wherein a width of a top of each of the key trenches in the first direction is a same as a width of a bottom of each of the key trenches in the first direction.

20. The method of claim 13,
wherein a width of a top of each of the key trenches in the first direction is between 1 μm and 3 μm.
